(19) United States
(12) Patent Application Publication
(10) Pub. No.: US 2005/0127474 A1
(43) Pub. Date: Jun. 16, 2005

(54) Semiconductor device and manufacturing method thereof

(75) Inventor: Takayuki Matsuda, Niigata (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/003,475

(22) Filed: Dec. 6, 2004

(30) Foreign Application Priority Data
Dec. 12, 2003 (JP) 2003-415038

(51) Int. Cl. H01L 29/76

(52) U.S. Cl. 257/510

(57) ABSTRACT

After thermally oxidizing a substrate in which a trench has been formed, a first insulating film having a higher film stress with a thickness of 30 to 80 nm is formed thereon through a CVD process under a high output power at a high temperature. Next, the substrate 1 is subjected to a heating treatment so as to allow defect areas to occur in the vicinity of a lower edge portion of the trench. Next, the trench is buried and an insulating film having a film stress that is lower than that of the first insulating film is deposited thereon, and, after a heating treatment, the insulating film is polished to form an embedded insulating film. Since stresses that are imposed from the insulating film in the post processes are concentrated on the defect areas, it becomes possible to prevent defect areas from occurring in the vicinity of the upper face of the substrate through which electric currents flow during operations of the semiconductor element.

### CROSS REFERENCES TO RELATED APPLICATIONS

This application claims benefit of priority under 35USC §119(a) to Japanese patent application No. 2003-415038, filed on Dec. 12, 2003, the contents of which are incorporated by reference herein.

### BACKGROUND OF THE INVENTION

1. Field of the Invention

The present invention relates to a semiconductor device and a manufacturing method thereof, and more specifically concerns a semiconductor device having a trench-type element separation area formed by embedding an insulating film in a trench formed in a semiconductor substrate, and a manufacturing method of such a semiconductor device.

2. Prior Art

In recent years, along with the miniaturization of a semiconductor device, an element-separation-forming method, that is, a so-called STI (Shallow-Trench-Isolation) method, in which, after forming a trench in a semiconductor substrate, an insulating film is embedded in the trench to form an element separation, has come to be widely used. In this element separation method using the STI method, no bird's beak is basically generated in comparison with an element separation using a conventional LOCOS method so that this method is advantageous in miniaturization (for example, see Japanese Patent Application. Laid-Open No. 2003-31648).

The following description will discuss a manufacturing method for a conventional semiconductor device in which an STI is formed. FIGS. 7A to 7E are cross-sectional views that illustrate manufacturing processes of the conventional semiconductor device.

First, after an oxide film, an amorphous silicon film and a nitride film have been successively formed on a semiconductor substrate 101 in a process shown in FIG. 7A, a dry etching process is carried out by using a resist film having an opening on an area to form an element separation area. Thus, the oxide film, the amorphous silicon film and the nitride film are etched to form an oxide film 120, an amorphous silicon film 102 and a nitride film 103 respectively. Moreover, by etching the semiconductor substrate 101 to a predetermined depth, a trench 104 is formed. Next, after the resist has been removed, the semiconductor substrate 101 is thermal-oxidized by using the nitride film 103 as a mask so that an oxide film 105 is formed on side face portions and a bottom portion of the trench 104 in the semiconductor substrate 101.

Next, in a process as shown in FIG. 7B, an insulating film 106, which has a film thickness that buries at least the trench 104 and is made of, for example, a silicon oxide film, is deposited over the entire surface of the substrate through a CVD method.

Then, in a process as shown in FIG. 7C, the insulating film 106 is flattened by using a chemical machine polishing (CMP) method so that the insulating film 106 is polished and removed until the nitride film 103 has been exposed; thus, an embedded insulating film 106a is formed inside the trench 104.

Successively, in a process shown in FIG. 7D, the nitride film 103, the amorphous silicon film 102 and the oxide film 120 are removed so that an element separation-use insulating film (isolation film) 107 in which the oxide film 105 and the embedded insulating film 106a have been embedded in the trench 104 is formed.

Next, in a process shown in FIG. 7E, an MIS-type transistor (MISFET), which has a gate insulating film 108, a gate electrode 111 made of a polysilicon electrode 109 and a metal electrode 110 (Ti/TiN/W), a gate-covering insulating film 112, a side wall 113 and source-drain areas 114, is formed on an active area made of the semiconductor substrate, by using a conventionally known method. Further, a gate wire 115, which has the same structure as the gate electrode 111, is formed on an element separation-use insulating film (isolation film) 107 having a narrow separation width and an element separation-use insulating film (isolation film) 117 having a wide separation width. The isolation film 117 is formed simultaneously with the isolation film 107. Both of the isolation films 107 and 117 include the oxide film 105 formed in the trench and the embedded insulating film 106a that has been formed on the oxide film 105 to bury the trench 104.

### SUMMARY OF THE INVENTION

In the above-mentioned conventional manufacturing method for a semiconductor device, since, after the formation of the trench 104 in an area to form the element-separation forming area of the semiconductor substrate 101, the oxide film 105 and the embedded insulating film 106a are formed inside the trench 104, the inside of the trench 104 formed in the semiconductor substrate 101 made from silicon is filled with the embedded insulating film 106a that is a dissimilar film. In the case where, in this state, an activation annealing process of ion-injected impurities and a gate oxide film formation through thermal oxidation are carried out in post processes, since there are differences in thermal expansion coefficient and shrinkage and expansion directions between the semiconductor substrate 101 and the embedded insulating film 106a at the time of heating treatment, portions of the semiconductor substrate 101, located on the sides of the upper trench portion, are subjected to a high stress, with the result that crystal defects (including crystal distortion) occur in the semiconductor substrate. For this reason, since a defect area 116 is formed in a bridging manner between MISFET source-drain areas 114 formed in the vicinity of the upper face of the semiconductor substrate 101 and the semiconductor substrate 101, an excessive leak current tends to occur between the source and drain, resulting in degradation in the reliability of the semiconductor device.

Here, the above description has exemplified a case in which an MISFET is formed as a semiconductor element; however, adverse effects due to crystal defects tend to occur in the same manner also in the case where a field-effect transistor, a bipolar transistor or the like other than the MISFET in which carriers pass through the vicinity of the upper face of the semiconductor substrate 101 during operations is formed thereon.

The objective of the present invention is to provide a semiconductor device which can reduce adverse effects given by crystal defects occurring due to formation of a trench-type element separation-use insulating film (isolation film) to operations of a semiconductor device, and consequently suppress occurrence of a leak current, and also to provide a manufacturing method for such a semiconductor device.

The semiconductor device of the present invention, which is provided with a semiconductor substrate in which a trench is formed and an element separation-use insulating film (isolation film), is arranged so that the isolation film has at least a first insulating film formed along side-face portions of the trench, and an embedded insulating film that is formed on or above the first insulating film, and buries the trench, and in the semiconductor substrate, crystal defects are formed in portions including bottom corner portions of the trench.

With this structure, even in the case where a stress is imposed from the embedded insulating film onto the semiconductor substrate located on the periphery of the trench due to a heating treatment or the like during the manufacturing processes, the crystal defects, located in the bottom corner portions of the trench, are allowed to expand so that the stress imposed on the other portions can be reduced; thus, it becomes possible to reduce crystal defects occurring on the periphery of the upper portion of the trench in the semiconductor substrate. For this reason, even in the case where an element, such as an MISFET and a bipolar transistor, in which carriers travel through a shallow area of a semiconductor substrate, is installed on the semiconductor substrate, it becomes possible to reduce leak currents in comparison with the conventional structure.

The first insulating film is allowed to have a higher film stress than that of the embedded insulating film so that crystal defects that occur in the semiconductor substrate during manufacturing processes are concentrated on the vicinity of bottom corner portions of the trench; thus, the range of crystal defects occurring on the periphery of the trench upper edge portion of the semiconductor substrate can be reduced.

Since the density of crystal defects contained in the bottom corner portions of the trench in the semiconductor substrate is higher than the density of crystal defects contained in the trench upper edge portion so that, even in the case where an element, such as an MISFET and a bipolar transistor, in which carriers travel through a shallow area of a semiconductor substrate, is formed on the semiconductor substrate, it becomes possible to reduce leak currents in comparison with the conventional structure.

Since the first insulating film is preferably formed from the bottom portion to the side portions of the trench, it is possible to effectively concentrate crystal defects occurring in the semiconductor substrate during manufacturing processes on the vicinity of the trench bottom corner portions.

The crystal defects contained in the trench bottom corner portions are formed within an area from the bottom face position of the trench to the upper face position of the first insulating film formed on the trench bottom portion, in height, so that upon forming the above-mentioned element on the semiconductor substrate, it is possible to prevent crystal defects from occurring in the semiconductor substrate on the periphery of the trench upper portion, and consequently to reduce leak currents in comparison with the conventional structure.

With respect to the first insulating film, the film thickness of the portion formed on each side face of the trench is made wider in the lower portion than in the upper portion so that the stress exerted from the first insulating film is concentrated, and applied to the bottom corner portions of the trench of the semiconductor substrate; thus, it becomes possible to reduce defect areas occurring on the periphery of the trench upper portion of the semiconductor substrate.

The first insulating film may be formed into a side wall shape on the trench side portion.

The film property of the first insulating film is made coarser than that of the embedded insulating film so that, when the first insulating film and the embedded insulating film are made from the same insulating material, the etching rate of the first insulating film becomes greater than the etching rate of the embedded insulating film; therefore, the upper face heights of the first insulating film and the embedded insulating film can be properly adjusted through etching.

The upper face position of the first insulating film is maintained higher than the upper face position of the semiconductor substrate and lower than the upper face position of the embedded insulating film so that, upon forming a semiconductor element, the film-thickness fluctuation of the resist film to be formed in the vicinity of the isolation film is made moderate so that it becomes possible to provide a fine patterning process.

The above-mentioned defect areas are formed within an area with a depth of not less than 200 nm from the upper face of the semiconductor substrate so that a portion in which a current flows during operation, such as the source-drain of an MISFET is not superposed on the defect areas; thus, it becomes possible to improve the operation reliability of an element to be formed on the semiconductor substrate.

The manufacturing method for a semiconductor device of the present invention, which relates to a manufacturing method for a semiconductor device having a semiconductor substrate in which a trench is formed and an element separation-use insulating film (isolation film) that buries the trench, is provided with step (a) of forming a first insulating film in the trench formed in the semiconductor substrate, step (b) of forming a defect area containing crystal defects on at least each of trench bottom corner portions of the semiconductor substrate by carrying out a heating treatment after the above-mentioned step (a), and step (c) of forming an embedded insulating film to bury the trench on or above the first insulating film so that an element separation-use insulating film (isolation film) having the first insulating film and the embedded insulating film is formed.

With this method, the defect areas are formed on each of the trench bottom corner portions in step (b); therefore, even upon receipt of a stress from the embedded insulating film upon formation of the embedded insulating film at step (c) or during heating treatment processes after ion injection to the semiconductor element, the defect areas in the vicinity of the trench bottom corner portions are allowed to expand and the stress is alleviated so that the portion of the semiconductor substrate located on the periphery of the trench upper portion is less susceptible to occurrence of defect areas. Consequently, upon forming a semiconductor element, such as an MISFET and a bipolar element, on a semiconductor substrate, it becomes possible to reduce leak currents occurring in the element in comparison with the conventional structure.

In the above-mentioned step (a), by forming the first insulating film into a concave shape along the trench, the stress is concentrated on the vicinity of the trench bottom corner portions in step (b) so that defect areas are allowed to occur therein.

Since the defect areas are formed in an area ranging from the bottom face position of the trench to the upper face position of the first insulating film formed on the trench bottom of the above-mentioned semiconductor substrate, in height, it is possible to suppress defect areas from occurring in the semiconductor substrate on the periphery of the trench upper portion in step (c) or steps thereafter, and consequently to reduce leak currents in comparison with the conventional structure when the element is formed on the semiconductor substrate.

With respect to the first insulating film formed in the above-mentioned step (a), the film thickness of the portion formed on each of the trench side faces is made greater in the lower portion than in the upper portion so that in step (b), the stress is concentrated on the vicinity of trench bottom corner portions to cause defect areas therein.

In the above-mentioned step (a), the first insulating film may be formed into a side wall shape on each of the side faces of the trench.

Since the first insulating film formed in the above-mentioned step (a) is allowed to have a higher film stress than that of the embedded insulating film formed in the above-mentioned step (c), the stress applied from the first insulating film becomes greater in step (b) so that defect areas are more positively allowed to occur in an area including the trench bottom corners.

In the above-mentioned step (b), the heating treatment is preferably carried out on the semiconductor substrate at a temperature of not less than 600° C. so that, in comparison with the heating treatment carried out at a temperature lower than 600° C., the residual stress of the first insulating film is made greater; thus, defect areas are more positively allowed to occur in the vicinity of trench bottom corner portions.

The film property of the first insulating film is made coarser than that of the embedded insulating film so that, when the first insulating film and the embedded insulating film are made from the same insulating material, the etching rate of the first insulating film becomes greater than the etching rate of the embedded insulating film; therefore, the upper face heights of the first insulating film and the embedded insulating film can be properly adjusted through etching.

The material forming the first insulating film is preferably deposited at a higher temperature under a higher output-power condition than the material forming the embedded insulating film so that, in general, the film property of the first insulating film is made coarser than the film property of the embedded insulating film.

Further, a step (d) in which, after the above-mentioned step (c), the first insulating film and the embedded insulating film are etched so that the upper face position of the first insulating film is placed higher than the upper face position of the semiconductor substrate, and is also maintained lower than the upper face position of the embedded insulating film is further prepared; thus, upon forming the semiconductor element, the film thickness fluctuation of the resist film to be formed in the vicinity of the isolation film is made milder so that it becomes possible to provide a finer patterning process.

### BRIEF DESCRIPTION OF THE DRAWINGS

FIG. 1 is a cross-sectional view that shows a semiconductor device in accordance with the first embodiment of the present invention.

FIGS. 2A to 2G are cross-sectional views that show manufacturing processes of the semiconductor device in accordance with the first embodiment of the present invention.

FIG. 3 is a cross-sectional view that shows a semiconductor device in accordance with the second embodiment of the present invention.

FIGS. 4A to 4G are cross-sectional views that show manufacturing processes of the semiconductor device in accordance with the second embodiment.

FIGS. 5A to 5D are cross-sectional views that show manufacturing processes of a semiconductor device in accordance with the third embodiment of the present invention.

FIG. 6 is a drawing that shows a relationship between a heating treatment temperature and a stress upon applying a heating treatment to an HDP-NSG film that has been formed.

FIGS. 7A to 7E are cross-sectional views that show manufacturing processes of a conventional semiconductor device.

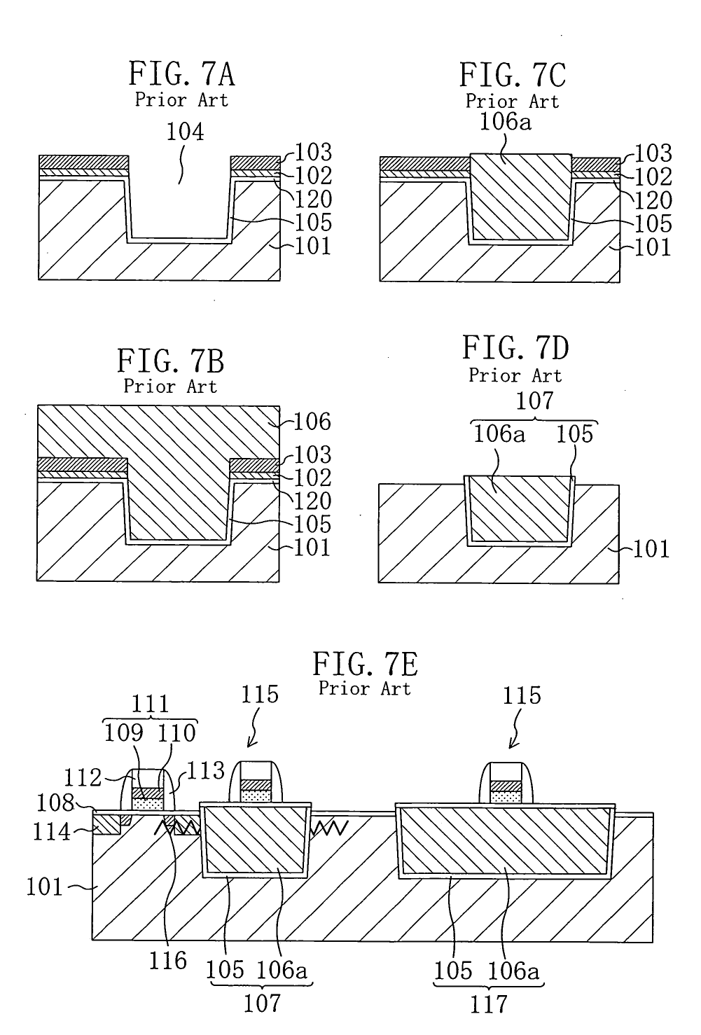

### DETAILED DESCRIPTION OF THE INVENTION

### First Embodiment

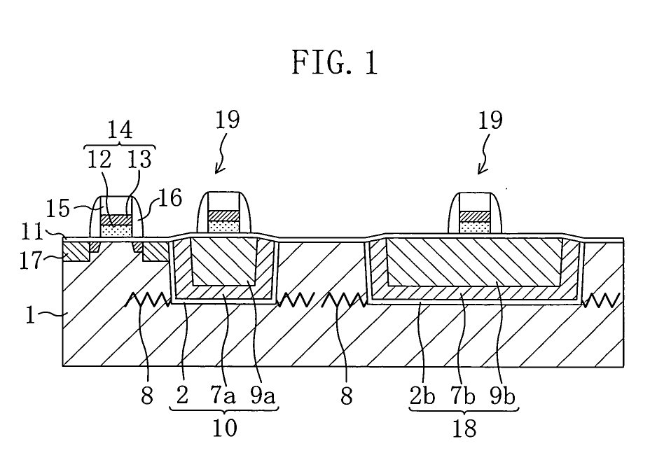

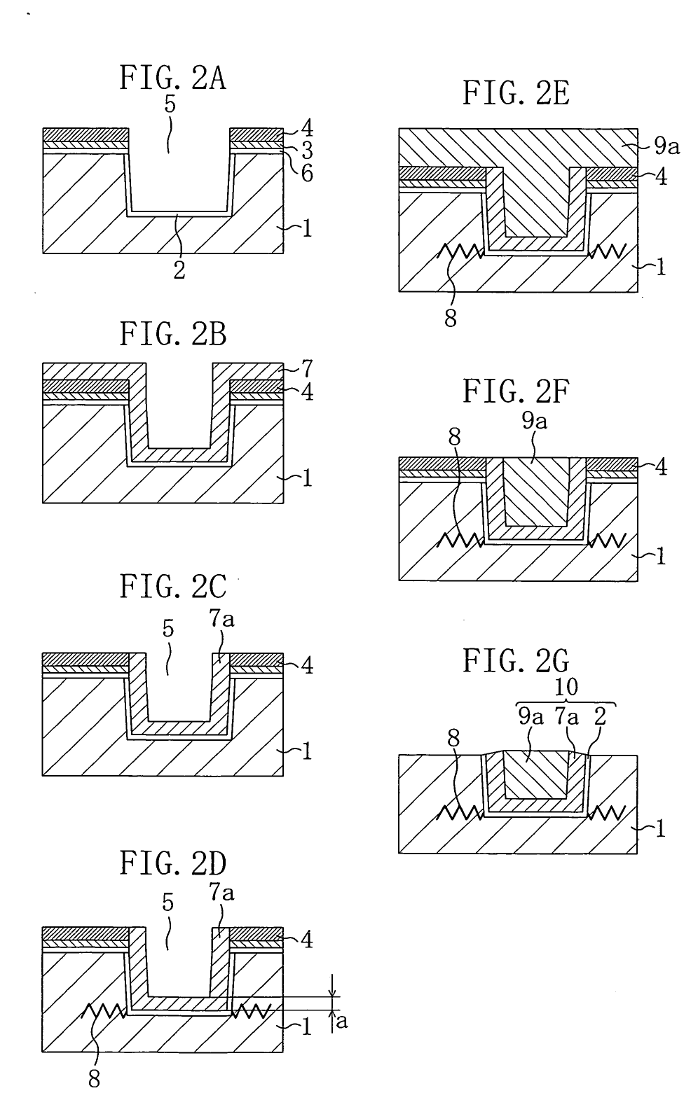

Referring to FIGS. 1 and 2, the following description will discuss a semiconductor device and a manufacturing method thereof in accordance with the first embodiment of the present invention.

FIG. 1 is a cross-sectional view that shows a semiconductor device in accordance with the first embodiment of the present invention, and FIGS. 2A to 2G are cross-sectional views that show manufacturing processes of the semiconductor device in accordance with the first embodiment of the present invention.

As shown in FIG. 1, the semiconductor device of the present embodiment, which has an active area and an element-separation area surrounding the active area, is provided with a semiconductor substrate 1 having a trench formed in the element-separation area, a field-effect transistor formed in the active area of the semiconductor substrate 1, element separation-use insulating films (isolation films) 10 and 18 that bury the trench within the element separation area, and gate wires 19 that are respectively formed on the isolation films 10 and 18. The trench formed inside the element-separation area preferably has a depth in a range from 200 nm or more to 600 nm or less.

In the example shown in FIG. 1, the field-effect transistor is an MISFET that is constituted by a gate insulating film 11 formed on the semiconductor substrate 1 made from, for example, silicon, a gate electrode 14 made of a polysilicon electrode 12 and a metal electrode 13 formed on the gate insulating film 11, a gate-covering insulating film 15 formed on the gate electrode 14, a side wall 16 formed on each of side faces of the gate electrode 14 and source-drain areas 17 that are formed on areas located on the two sides of the gate electrode 14 of the semiconductor substrate 1. Moreover, the gate wire 19 has, for example, the same structure as the field-effect transistor.

The isolation film 10 is provided with a coat insulating film 2 that is placed on the inner walls of the trench, and made from a silicon oxide having a thickness in a range from 5 to 20 nm, a first insulating film 7a that is formed on the coat insulating film 2, and made from a silicon oxide (HDP-NSG) having a thickness in a range from 30 nm or more to 80 nm or less, and an embedded insulating film 9a that is formed on the first insulating film 7a and buries the trench. Here, the first insulating film 7a is different from the embedded insulating film 9a in its film property so that it gives a greater stress to the semiconductor substrate 1. With respect to the material for the embedded insulating film 9a, silicon oxide may be used, or a silicon nitride film may be used.

Moreover, the isolation film 18 has virtually the same structure as the isolation film 10. In other words, the isolation film 18 is provided with a coat insulating film 2b that is placed on the inner walls of the trench, and made from a silicon oxide having a thickness in a range of 5 to 20 nm, a first insulating film 7b that is formed on the coat insulating film 2b, and made from a silicon oxide (HDP-NSG) having a thickness in a range from 30 nm or more to 80 nm or less, and an embedded insulating film 9b that is formed on the first insulating film 7a, and buries the trench. Here, the width of the isolation film 10 in the gate length direction is set to, for example, 2 μm or less, and the width of the isolation film 18 is set to, for example, more than 2 μm.

The semiconductor device of the present embodiment is characterized by the structures of the above-mentioned isolation films 10 and 18, and these structures allow defect areas 8 containing crystal defects to occur on the periphery of the lower edge portion (bottom corner portions; indicating corner portions of the trench bottom) of the semiconductor substrate 1. Here, in the present specification, the lower edge portions (or bottom corner portions) of the trench refer to portions at which the side face of the trench and the bottom face are brought into contact with each other.

Many of these defect areas 8 are seen in an area having a depth of not less than 200 nm from the upper face of the semiconductor substrate 1. In contrast, in an area having a depth of not more than 150 nm from the upper face of the semiconductor substrate 1 on the periphery of the trench, hardly any defect areas are seen, or the number of the defect areas becomes much smaller than that in the area having a depth of not less than 200 nm. Moreover, the defect areas 8 containing crystal defects are mainly located in areas within 200 nm from each of the isolation films 10 and 18.

In contrast, the source-drain areas 17 of the MISFET are formed in areas having a depth within 150 nm from the upper face in the semiconductor substrate 1; therefore, hardly any defect areas 8 are seen inside the source-drain areas 17, with the result that the density of crystal defects is greatly reduced in comparison with the conventional semiconductor device. For this reason, in the semiconductor device of the present embodiment, it becomes possible to reduce leak currents occurring in the source-drain areas 17 and a channel area between the source-drain areas 17 during operation of the MISFET.

Therefore, the semiconductor device of the present embodiment makes it possible to improve the operation reliability of the element formed on the semiconductor substrate 1.

Next, referring to FIG. 2, the following description will discuss a manufacturing method for the above-mentioned semiconductor device. This figure has exemplified a peripheral portion of the isolation film 10.

First, in a process shown in FIG. 2A, after a silicon oxide film 6, an amorphous silicon film 3, and a silicon nitride film 4 have been successively formed on a p-type semiconductor substrate 1, the silicon nitride film 4, the amorphous silicon film 3 and the silicon oxide film 6 are etched through dry etching by using a resist film (not shown) having an opening on an area to form an element-separation-forming area so that a patterning process is carried out. Successively, the semiconductor substrate 1 is further etched to a predetermined depth, for example, to a depth in a range from 200 to 600 nm, to form a trench 5. When the depth of the trench is too shallow, defect areas 8 occurring in the following process come to enter the source-drain areas of the MISFET; therefore, the depth of the trench is preferably set to not less than 200 nm.

Next, after having removed the resist, the semiconductor substrate 1 is thermal-oxidized in a dry O₂ atmosphere at 1000 to 1300° C. by using the silicon nitride film 4 as a mask so that a coat insulating film 2 having a thickness of 5 to 20 nm is formed on the inner walls (side faces and bottom face) of the trench 5. This oxidizing process allows the corner portions of the semiconductor substrate 1 located on the upper edge portions of the trench 5 to be oxidized and rounded.

Next, in a process shown in FIG. 2B, a first insulating film 7, made from a silicon oxide (HDP-NSG) having a thickness in a range from 30 nm or more to 80 nm or less, is formed on the entire surface of the substrate under formation conditions of an output of 4.0 kW at 600° C., by using a high-density plasma method. At this time, with respect to the material for the first insulating film 7, not limited to HDP-NSG, any insulating film may be used as long as it is an insulating film having a high tensile component with a high film stress. Here, the film thickness of the first insulating film 7 is set to 80 nm or less because it is necessary to adjust the film thickness so as not to completely bury the trench, and it is set to 30 nm or more because it is necessary for the first insulating film 7 (7a) to apply a stress to the semiconductor substrate 1 in a manner so as to cause defect areas 8 in the succeeding heating treatment process.

Next, in a process shown in FIG. 2C, the first insulating film 7 on the silicon nitride film 4 is removed through a CMP method so that the first insulating film 7a is allowed to remain only inside the trench 5. Here, the first insulating film 7a forms a concave shape along the trench 5.

Next, in a process shown in FIG. 2D, the semiconductor substrate 1 is subjected to a high-temperature heating treatment at a temperature range of 600 to 1300° C. for a treatment time of 10 to 40 minutes in an N₂ atmosphere. At this time, since the first insulating film 7a, which has a high tensile component with a high film stress, is present inside the trench 5, a higher stress is imposed on a portion of the semiconductor substrate 1 located on the periphery of the lower edge portion (bottom corner portions) of the trench 5 in comparison with a portion of the semiconductor substrate 1 located on the periphery of the upper edge portion of the trench 5. This is because the portion of the semiconductor substrate 1 located on the periphery of the lower edge portion of the trench 5 is subjected to a stress from the first insulating film 7a, while the portion on the periphery of the upper edge portion of the trench 5 is released from the stress since there is a space located above. As a result, crystal defects or defect areas 8 having residual stress occur in the vicinity (“a” shown in FIG. 2D) of the lower edge portion (bottom corner portions) of the trench 5 in the semiconductor substrate 1. Here, the crystal defects and defect areas 8 are formed within the film thickness of the first insulating film 7a formed on the bottom of the trench 5. Since the depth of the trench 5 is generally set to not less than 200 nm, the depth of the crystal defects and defect areas 8 is also set to virtually not less than 200 nm. Moreover, the crystal defects and defect areas 8 mainly occur in an area of the semiconductor substrate 1 having a distance from the trench (or the first insulating film 7a) of not more than 200 nm.

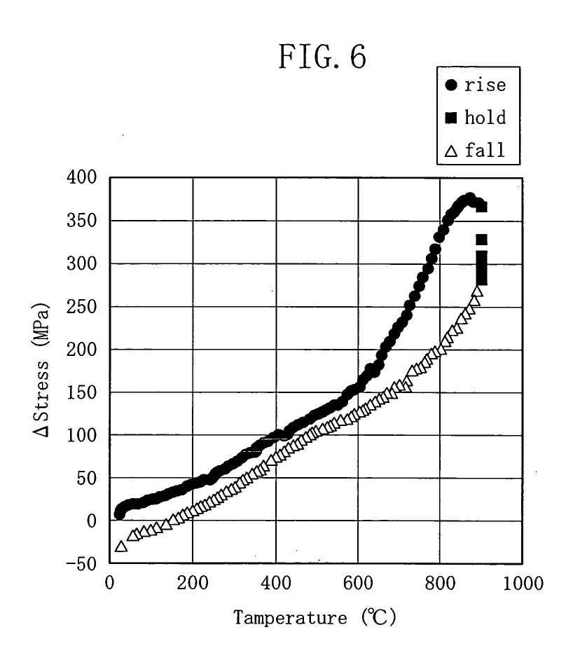

Here, FIG. 6 is a graph that shows a relationship between the heating treatment temperature and the stress upon applying the heating treatment with the HDP-NSG film being formed.

As shown in this figure, when the heating treatment temperature becomes not less than 600° C., the difference between the stress at the time of a temperature rise (“rise” in the figure) and the stress at the time of a temperature fall (“fall” in the figure) becomes greater so that the residual stress after the heating treatment also becomes greater. Therefore, the heating treatment temperature in the present process is preferably set to not less than 600° C. so that the crystal defects or defect areas 8 are more positively allowed to occur.

Next, in a process shown in FIG. 2E, an insulating film 9, made from HDP-NSG having a thickness in a range from 400 nm to 600 nm, is formed on the entire surface of the substrate under formation conditions of 3.0 kW at 420° C., by using a high-density plasma method. In this process, the amount of deposition of HDP-NSG is adjusted in accordance with the depth of the trench so as to allow the insulating film 9 to sufficiently bury the trench. Here, both of the insulating film 9 and the first insulating film 7 (7a) are made from HDP-NSG, and the insulating film 9 is formed under a lower power at a lower temperature, in comparison with the first insulating film 7a. Thus, the film stress of the insulating film 9 can be made smaller than that of the first insulation film 7a.

Thereafter, a hardening-anneal process is carried out under conditions of a temperature range of 900 to 1200° C. and a treatment time of 15 to 60 minutes so that the insulating film 9 is baked and hardened. At this time, by a stress applied to the semiconductor substrate 1 through the hardening-anneal process, the crystal defects generated in the process shown in FIG. 2D are allowed to extend or the defect areas 8 are allowed to expand. Here, the occurrence of the crystal defects and defect areas 8 is mainly limited to an area having a distance within 200 nm from the trench.

In this manner, the crystal defects and defect areas 8, located in the vicinity of the lower edge portion of the trench 5, are extended or expanded so that the stress to be imposed on the semiconductor substrate 1 from the insulating film 9 can be cancelled so that the stress to be applied to the active areas to form the source-drain areas is alleviated in comparison with the conventional structure, thereby making it possible to prevent occurrence of the crystal defects and defect areas 8 in the vicinity of the upper face of the semiconductor substrate 1.

Next, in a process shown in FIG. 2F, a flattening process is carried out on the insulating film 9 by using a CMP method. By removing the insulating film 9 to such an extent that the silicon nitride film 4 is exposed in this process, an embedded insulating film 9a is formed inside the trench 5.

Then, in a process shown in FIG. 2G, a wet-etching process is carried out on the embedded insulating film 9a in order to adjust the height of the embedded insulating film 9a with respect to the upper face of the semiconductor substrate 1. Further, the silicon nitride film 4, the amorphous silicon film 3 and the silicon oxide film 6 are removed. Through these processes, an element separation-use insulating film (isolation film) 10 having the coat insulating film 2 placed on the inner walls of the trench 5, the first insulating film 7a and the embedded insulating film 9a is formed.

Moreover, the isolation film 18 having the coat insulating film 2, the first insulating film 7b and the embedded insulating film 9b is formed simultaneously with the isolation film 10.

Thereafter, as shown in FIG. 2, an MISFET, which has a gate insulating film 11, a polysilicon electrode 12, a gate electrode 14 made of a metal electrode 13 made from Ti (titanium), TiN (titanium nitride), W (tungsten) or a laminated member of these, a gate-covering insulating film 15, side walls 16 and source-drain areas 17, is formed on the active area of the semiconductor substrate 1 by using conventional techniques.

Successively, on the narrow isolation film 10 having a separation width of not more than 2 μm and the wide isolation film 18 having a separation width exceeding 2 μm, gate wires 19 (not shown) having the same structure as the gate electrode structure of the MISFET are respectively formed. The semiconductor device of the present embodiment is formed in this manner.

In accordance with this method, in a process shown in FIG. 2D, the heating treatment is carried out in a state in which the first insulating film 7a, which has a higher film stress than the conventional embedded insulating film, is not formed above the semiconductor substrate 1 within the active area; therefore, crystal defects and defect areas 8 are allowed to occur in the vicinity of the lower edge portion of the trench in the semiconductor substrate 1. Upon receipt of a stress in this state during the heating treatment of the embedding-use insulating film 9, the stress is concentrated on the crystal defects and defect areas 8 so that the crystal defects and the defect areas 8 are allowed to extend or expand; thus, it is possible to prevent the defect areas 8 from occurring within an area having a depth of not more than 150 nm of the semiconductor substrate 1 during the manufacturing process. Moreover, since the depth of the source-drain areas 17 of the MISFET formed on the semiconductor substrate 1 is set, for example, in a range from 50 nm to 150 nm, it is possible to prevent the defect areas 8 from being formed in a manner so as to cross the source-drain areas 17; thus, it becomes possible to reduce occurrence of leak currents between the source and drain.

In this embodiment, an MISFET is exemplified as an element to be formed on the semiconductor substrate 1; however, in addition to a field-effect transistor in which carriers flow in the vicinity of the upper face of the semiconductor substrate 1, a bipolar transistor or the like may be formed with the same effects.

Here, in the present embodiment, an HDP-NSG film is used as the first insulating film 7; however, since the defect areas 8 are allowed to occur in the vicinity of the bottom portion of the trench as long as the first insulating film 7 is an insulating film having a higher-stress film property in comparison with the insulating film 9, a silicon nitride film formed, for example, through an LP-CVD method may be used with the same effects. Moreover, with respect to the insulating film 9, any film other than the HDP-NSG film may be used, as long as the insulating film has a lower stress than the first insulating film 7, with a good embedding property. In this case also, it is possible to provide the same effects as the present invention.

Additionally, in the method explained in the present embodiment, it is preferable to form the coat insulating film 2 so as to round the corners of the trench; however, without the formation of the coat insulating film 2, it is possible to obtain the effects for improving the operational reliability in the MISFET.

Moreover, a silicon substrate is preferably used as the semiconductor substrate 1; however, an SOI substrate, an SiC (silicon carbide) substrate, an SiGe substrate or the like, which have an insulating film embedded in a lower portion of the substrate, may be used as well.

Here, a polysilicon film may be formed in place of the amorphous silicon film 3, and it becomes possible to obtain the same effects as the semiconductor device of the present embodiment.

### Second Embodiment

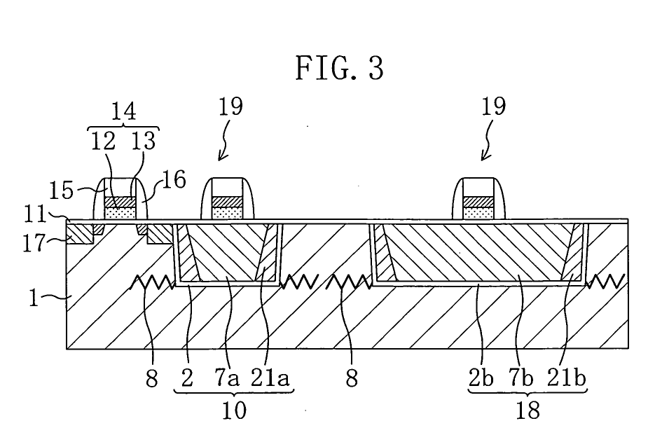

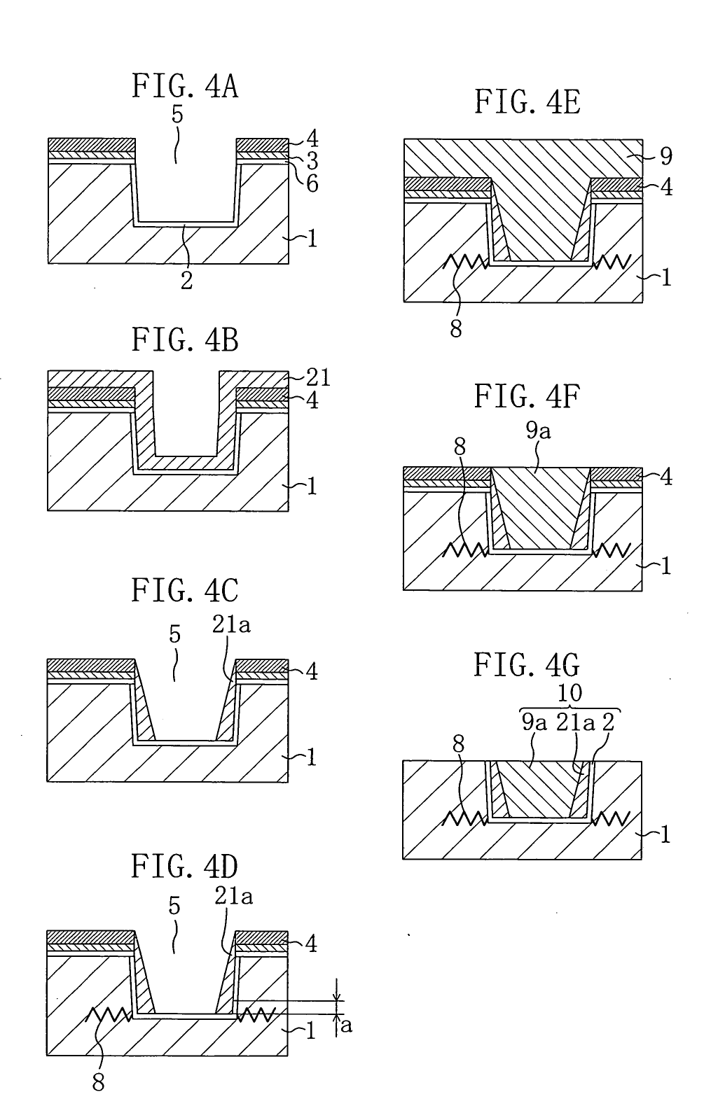

FIG. 3 is a cross-sectional view that shows a semiconductor device in accordance with the second embodiment of the present invention, and FIGS. 4A to 4G are cross-sectional views that show manufacturing processes of the semiconductor device in accordance with the second embodiment of the present invention.

As shown in FIG. 3, the semiconductor device of the present embodiment differs from the semiconductor device of the first embodiment only in the shapes of the first insulating films 21a and 21b.

In other words, the semiconductor device of the present embodiment, which has an active area and an element-separation area surrounding the active area, is provided with a semiconductor substrate 1 having a trench formed in the element-separation area, a field-effect transistor formed in the active area of the semiconductor substrate 1, element separation-use insulating films (isolation film) 10 and 18 that bury the trench within the element separation area, and gate wires 19 that are respectively formed on the isolation films 10 and 18. The trench formed inside the element-separation-use area preferably has a depth in a range from 200 nm or more to 600 nm or less.

The isolation film 10 is provided with a coat insulating film 2 that is placed on the inner walls of the trench, and made from a silicon oxide having a thickness in a range of 5 to 20 nm, a first insulating film 21a that is formed on the side walls of the coat insulating film 2, and has a side wall shape made from a silicon oxide (HDP-NSG), and an embedded insulating film 9a that is formed on the coat insulating film 2 and the first insulating film 21a and buries the trench. Here, the film thickness of the first insulating film 21a is made thicker in the lower portion than in the upper portion within the trench. The thickness of the lower-most portion of the first insulating film 21a that is brought into contact with the bottom face of the coat insulating film 2 is set in a range from 30 nm or more to 80 nm or less. Here, the “side wall shape” refers to the same shape as the side walls that are formed on the side faces of the MISFET gate electrode, and, more specifically, refers to the shape that covers the trench side faces, and is located only on the periphery of the trench bottom face in its plan view.

Here, the first insulating film 21a is different from the embedded insulating film 9a in its film property so that it gives a greater stress to the semiconductor substrate 1. With respect to the material for the embedded insulating film 9a, silicon oxide may be used, or a silicon nitride film may be used.

Moreover, the isolation film 18 has virtually the same structure as the isolation film 10.

In other words, the isolation film 18 is provided with a coat insulating film 2b that is placed on the inner walls of the trench, and made from a silicon oxide having a thickness in a range of 5 to 20 nm, a first insulating film 21b that is formed on each of the side walls of the coat insulating film 2b, and has, for example, a side wall shape made from HDP-NSG, and an embedded insulating film 9b that is formed on the coat insulating film 2 and the first insulating film 21b and buries the trench.

In the same manner as the semiconductor device of the first embodiment, in the semiconductor device of the present embodiment, defect areas 8 containing crystal defects are present on the periphery of the lower edge portion of the trench of the semiconductor substrate 1. Many of these defect areas 8 are seen in an area having a depth of not less than 200 nm from the upper face of the semiconductor substrate 1. In contrast, in an area having a depth of not more than 150 nm from the upper face of the semiconductor substrate 1 on the periphery of the trench, hardly any defect areas are seen, or the number of the defect areas becomes much smaller than that in the area having a depth of not less than 200 nm. Moreover, in the semiconductor device of the present embodiment, stresses to be applied to the vicinity of the trench upper portion of the semiconductor substrate 1 are made smaller in comparison with the first embodiment; therefore, the density of crystal defects occurring in the vicinity of the upper face of the semiconductor substrate 1 is further lowered to make the defects areas 8 smaller.

Next, the following description will discuss a manufacturing method for the above-mentioned semiconductor device.

First, in a process shown in FIG. 4A, after a silicon oxide film 6, an amorphous silicon film 3 and a silicon nitride film 4 have been successively formed on a p-type semiconductor substrate 1, the silicon nitride film 4, the amorphous silicon film 3 and the silicon oxide film 6 are etched through dry etching by using a resist film (not shown) having an opening on an area to form an element-separation-forming area so that a patterning process is carried out. Successively, the semiconductor substrate 1 is further etched to a predetermined depth, for example, to a depth in a range from 200 to 600 nm, to form a trench 5. When the depth of the trench is too shallow, defect areas 8 occurring in the following process come to enter the source-drain areas of the MISFET; therefore, the depth of the trench is preferably set to not less than 200 nm.

Next, after having removed the resist, the semiconductor substrate 1 is thermal-oxidized in a dry O₂ atmosphere at 1000 to 1300° C. by using the silicon nitride film 4 as a mask so that a coat insulating film 2 having a thickness of 5 to 40 nm is formed on the inner walls (side faces and bottom face) of the trench 5. This oxidizing process allows the corner portions of the semiconductor substrate 1 located on the upper edge portions of the trench 5 to be oxidized and rounded.

Next, in a process shown in FIG. 4B, a first insulating film 21, made from a silicon oxide (HDP-NSG) having a thickness in a range from 30 nm or more to 80 nm or less, is formed on the entire surface of the substrate under formation conditions of 4.0 kW at 600° C., by using a high-density plasma method. At this time, with respect to the material for the first insulating film 21, not limited to HDP-NSG, any insulating film may be used as long as the insulating film has a high tensile component with a high film stress (for example, higher than the thermal oxide film). Here, with respect to the film thickness of the first insulating film 21, it is important to adjust it so as not to completely bury the trench. The processes to be carried out up to this point are the same as the first embodiment.

Next, in a process shown in FIG. 4C, the first insulating film 21 is etched back through an anisotropic dry etching so that the first insulating films 21a having the side wall shape are formed only on the side wall faces inside the trench 5.

Next, in a process shown in FIG. 4D, the semiconductor substrate 1 is subjected to a high-temperature heating treatment at a heating temperature range of 600 to 1300° C. for a treatment time of 10 to 40 minutes. At this time, although the first insulating film 21a, which has a high tensile component with a high film stress, is present on the side faces of the trench 5, stresses to be applied to the semiconductor substrate 1 are different depending on the vicinity of the upper portion and the vicinity of the lower portion of the trench 5. In other words, in the vicinity of the lower portion of the trench 5 of the semiconductor substrate 1, the film thickness of the first insulating film 21a having the side wall shape is made thicker in comparison with the vicinity of the upper portion of the trench. For this reason, in the vicinity of the upper portion of the trench 5, the film thickness of the first insulating film 21a is made thinner than the film thickness of the first insulating film 7a of the first embodiment, and no first insulating film 21a is formed on the semiconductor substrate 1 except for the trench portion; therefore, stresses are released, and hardly any stress is imposed on the semiconductor substrate 1.

In contrast, in the vicinity of the lower portion of the trench 5 of the semiconductor substrate 1, the film thickness of the first insulating film 21a is made thicker than the film thickness thereof in the vicinity of the upper portion so that stresses are concentrated, with the result that the stresses are imposed on the lower edge portion (bottom corner portions) of the trench 5 due to the high-temperature heating treatment to cause occurrence of defect areas 8. Here, in the same manner as the first embodiment, the crystal defects and defect areas 8 are formed within the film thickness of the first insulating film 21a formed on the bottom of the trench 5. Additionally, the defect areas 8 mainly occur in an area having a depth of not less than 200 nm from the upper face of the semiconductor substrate 1. Moreover, in view of the results shown in FIG. 6, the heating treatment temperature in the present process is preferably set to not less than 600° C. in the same manner as the first embodiment.

Next, in a process shown in FIG. 4E, an insulating film 9, made of an HDP-NSG film having a thickness in a range from 400 nm to 600 nm, is formed on the entire surface of the substrate under formation conditions of 3.0 kW at 420° C., by using a high-density plasma method. In this process, with respect to the insulating film 9, the depositing process is carried out under HDP-NSG film deposition conditions of a lower power and a lower temperature, in comparison with the first insulating film 21. Thereafter, in order to bake and harden the insulating film 9, a hardening-anneal process is carried out under conditions of a temperature range of 900 to 1200° C. and a treatment time of 15 to 60 minutes. At this time, a stress applied to the semiconductor substrate 1 by the hardening-anneal process is absorbed by the growth of the defect areas 8 in the vicinity of the lower edge portion (bottom corner portions) of the trench 5 so that the stress to be applied to the vicinity of the upper portion of the trench 5 of the semiconductor substrate 1 is alleviated in comparison with the conventional semiconductor device. For this reason, the device is less susceptible to occurrence of the defect areas 8 in a portion to form the MISFET source-drain areas in the following processes.

Next, in a process shown in FIG. 4F, a flattening process is carried out on the insulating film 9 by using a chemical machine polishing (CMP) method so that the insulating film 9 on the silicon nitride film 4 is removed to form an embedded insulating film 9a inside the trench 5.

Then, in a process shown in FIG. 4G, a wet-etching process is carried out on the embedded insulating film 9a in order to adjust the height of the embedded insulating film 9a with respect to the upper face of the semiconductor substrate 1. Further, the silicon nitride film 4, the amorphous silicon film 3 and the silicon oxide film 6 are removed so that an element separation-use insulating film (isolation film) 10, which has the coat insulating film 2, the first insulating film 21a and the embedded insulating film 9a placed inside the trench 5, is formed.

Moreover, the isolation film 18 having the coat insulating film 2, the first insulating film 21b and the embedded insulating film 9b is formed simultaneously with the isolation film 10.

Thereafter, as shown in FIG. 3, an MISFET, which has a gate insulating film 11, a polysilicon electrode 12, a gate electrode 14 made of a metal electrode 13 made from Ti, TiN, W or a laminated member of these, a gate-covering insulating film 15, side walls 16 and source-drain areas 17, is formed on the active area of the semiconductor substrate 1 by using conventional techniques. Successively, on the narrow isolation film 10 having a separation width of not more than 2 μm and the wide isolation film 18 having a separation width exceeding 2 μm, gate wires 19 having the same structure as the gate electrode structure of the MISFET are respectively formed. The semiconductor device of the present embodiment is formed in this manner.

In accordance with this method, in a process shown in FIG. 4D, the heating treatment is carried out in a state in which the first insulating film 21a with the side wall shape, which has a higher film stress than the conventional embedded insulating film, is placed on the side walls of the trench 5 (or the coat insulating film 2); therefore, crystal defects and defect areas 8 are allowed to occur in the vicinity of the lower edge portion of the trench in the semiconductor substrate 1. In particular, since the film thickness of the first insulating film 21a is made thicker in the lower portion than in the upper portion, stresses to be applied to the semiconductor substrate 1 in the vicinity of the upper portion of the trench 5 are reduced in comparison with the first embodiment so that the stresses are directed and concentrated on the semiconductor substrate 1 in the vicinity of the lower edge portion of the trench 5. Consequently, the crystal defects and the defect areas 8 are allowed to extend or expand so that it becomes possible to effectively prevent defect areas 8 from occurring within an area having a depth of not more than 150 nm of the semiconductor substrate 1 during the manufacturing process. Here, since the depth of the source-drain areas 17 of the MISFET formed on the semiconductor substrate 1 is set, for example, in a range from 50 nm to 150 nm, it is possible to prevent the defect areas 8 from being formed in a manner so as to cross the source-drain areas 17, and consequently to reduce occurrence of leak currents between the source and drain.

Here, in the present embodiment, an HDP-NSG film is used as the first insulating film 21; however, any insulating film may be used for generating defect areas 8 in the vicinity of the trench bottom portion as long as it allows the first insulating film 21 to have a film property with a higher stress than that of the insulating film 9. For example, a silicon nitride film formed by an LP-CVD method may be used with the same effects. Moreover, with respect to the insulating film 9, any film other than the HDP-NSG film may be used, as long as the insulating film has a low stress with a good embedding property; and it becomes possible to obtain the same effects as the present invention.

Here, the present embodiment has exemplified a case in which the first insulating film 21a has a side wall shape; however, as long as the film thickness of the first insulating film 21a formed above the side walls of the trench 5 is made thicker in the lower portion than in the upper portion, stresses are applied to the bottom corner portions of the trench even when the first insulating film 21a is formed above the bottom face of the trench 5. Therefore, it is possible to obtain the same effects as the present embodiment.

### Third Embodiment

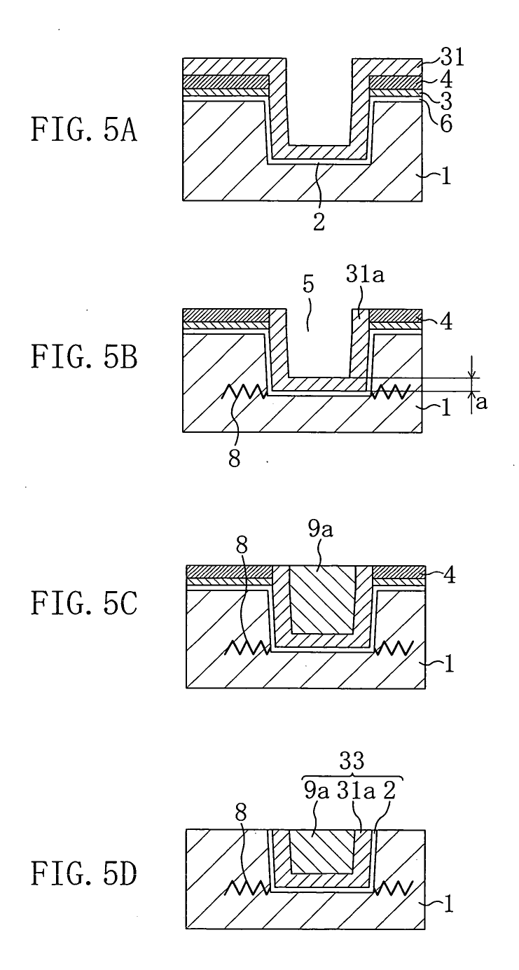

FIGS. 5A to 5D are cross-sectional views that show manufacturing processes of the semiconductor device in accordance with the third embodiment of the present invention.

The manufacturing method for the semiconductor device of the present embodiment is almost the same as the manufacturing method of the first embodiment, except that the film property of a first insulating film 31a is different from that of the first embodiment. The following description will discuss the point that is different from the first embodiment.

First, in a process shown in FIG. 5A, after a trench 5 has been formed on a semiconductor substrate 1 in the same manner as the first embodiment, a first insulating film 31 having a thickness of 30 to 80 nm, which has a film stress higher than that of the conventional isolation film, is formed in the trench 5, through a thermal CVD method or a plasma CVD method, by using organic silicon as a main material. At this time, in order to make the film property of the first insulating film 31 coarser than that of an insulating film 9 to be formed later, the first insulating film 31 is formed under film forming conditions having a higher output power and a higher temperature than the film forming conditions of the insulating film 9. For example, in the case where the high-density plasma (HDP) CVD method is used, the insulating film 31 is formed under conditions of 4.0 kW at 600° C. Under these deposition conditions, since the film-forming reaction of the first insulating film 31 progresses faster than the film-forming reaction of the insulating film 9, the first insulating film 31 is made to have a coarse film property containing many side reaction products, with a high tensile component; thus, this film property exerts a great etching rate with respect to a solution containing HF.

Next, in a process shown in FIG. 5B, after polishing the first insulating film 31 to form the first insulating film 31a in the same manner as the first embodiment, the substrate is subjected to a heating treatment to cause occurrence of defect areas 8 in the semiconductor substrate 1 on the periphery of the lower edge portion of the trench.

Thereafter, in a process shown in FIG. 5C, an insulating film 9 having a good embedding property is formed on the substrate. Next, the insulating film 9 is polished through the CMP method to form an embedded insulating film 9. Through this CMP process, the upper faces of the first insulating film 31a and the embedded insulating film 9a are normally maintained higher than the upper face of the semiconductor substrate 1 within the active area. Next, in order to adjust the height of the embedded insulating film 9a, a wet etching process is carried out thereon by using a solution containing HF. At this time, since the first insulating film 31 has a greater etching rate with respect to the solution containing HF than the embedded insulating film 9a, the height of the embedded insulating film 9a is effectively lowered. By allowing the first insulating film 31a to have a coarse structure in this manner, it becomes possible to prevent the height of the embedded insulating film 9a from becoming higher than the peripheral portion, even within an area in which patterns are closely located.

Next, the silicon nitride film 4, amorphous silicon film 3 and silicon oxide film 6 are removed to form an element separation-use insulating film (isolation film) 33.

In accordance with the above-mentioned method, since the etching rate to HF is made greater by allowing the first insulating film 31a to have a coarser structure than the embedded insulating film 9a, it becomes possible to make the step difference between the upper face of the isolation film 33 and the upper face of the semiconductor substrate 1. Thus, upon forming a fine gate electrode through a lithography process, the film-thickness fluctuation of the resist is alleviated in the vicinity of the isolation film 33 so that it becomes possible to carry out a fine patterning process. For this reason, in an attempt to form a finer gate electrode in comparison with the conventional semiconductor device, it becomes possible to alleviate fluctuations in the resist film thickness, and consequently to easily carry out the patterning process. As a result, the reliability of the semiconductor device having a fine gate electrode can be improved.

Here, the semiconductor device of the present invention is used for controlling operations of various apparatuses, such as electric apparatuses, personal computers and electrical home appliances.

1. A semiconductor device comprising:
a semiconductor substrate in which a trench is formed; and
an element separation-use insulating film (isolation film) that buries the trench,
wherein: the isolation film has at least a first insulating film formed along a side-face portion of the trench, and an embedded insulating film that is formed on or above the first insulating film, and buries the trench, and crystal defects are formed in portions including bottom corner portions of the trench of the semiconductor substrate.

2. The semiconductor device of claim 1, wherein the first insulating film has a higher film stress than that of the embedded insulating film.

3. The semiconductor device of claim 1, wherein the density of crystal defects contained in the bottom corner portions of the trench in the semiconductor substrate is higher than the density of crystal defects contained in the trench upper edge portion.

4. The semiconductor device of claim 1, wherein the first insulating film is formed from the bottom portion to the side portion of the trench.

5. The semiconductor device of claim 4, wherein the crystal defects contained in the trench bottom corner portions are formed within an area from the bottom face position of the trench to the upper face position of the first insulating film formed on the trench bottom portion, in height, in the semiconductor substrate.

6. The semiconductor device of claim 1, wherein, with respect to the first insulating film, the film thickness of the portion formed on each side face of the trench is made wider in the lower portion than in the upper portion.

7. The semiconductor device of claim 6, wherein the first insulating film is formed into a side wall shape on the side-face portion of the trench.

8. The semiconductor device of claim 1, wherein the film property of the first insulating film is made coarser than that of the embedded insulating film.

9. The semiconductor device of claim 8, wherein the upper face position of the first insulating film is maintained higher than the upper face position of the semiconductor substrate and lower than the upper face position of the embedded insulating film.

10. The semiconductor device of claim 1, wherein crystal defects contained in the corner portions of the trench are formed within an area with a depth of not less than 200 nm from the upper face of the semiconductor substrate.

11. A manufacturing method for a semiconductor device, which manufactures a semiconductor device having a semiconductor substrate in which a trench is formed and an element separation-use insulating film that buries the trench, comprising the steps of:
(a) forming a first insulating film in the trench formed in the semiconductor substrate;
(b) forming a defect area containing crystal defects on at least each of trench bottom corner portions of the semiconductor substrate by carrying out a heating treatment after step (a); and
(c) forming an embedded insulating film to bury the trench on or above the first insulating film so that an element separation-use insulating film having the first insulating film and the embedded insulating film is formed.

12. The manufacturing method of claim 11, wherein in step (a), the first insulating film is formed into a concave shape along the trench.

13. The manufacturing method for a semiconductor device of claim 12, wherein the defect area is formed in an area ranging from the bottom face position of the trench to the upper face position of the first insulating film formed on the trench bottom, in height, of the semiconductor substrate.

14. The manufacturing method for a semiconductor device of claim 11, wherein, with respect to the first insulating film formed in step (a), the film thickness of the portion formed on each of the trench side faces is made greater in the lower portion than in the upper portion.

15. The manufacturing method for a semiconductor device of claim 14, wherein in step (a), the first insulating film is formed into a side wall shape on each of the side faces of the trench.

16. The manufacturing method for a semiconductor device of claim 11, wherein the first insulating film formed in step (a) has a higher film stress than that of the embedded insulating film formed in step (c).

17. The manufacturing method for a semiconductor device of claim 11, wherein in step (b), the heating treatment is carried out on the semiconductor substrate at a temperature of not less than 600° C.

18. The manufacturing method for a semiconductor device of claim 11, wherein the film property of the first insulating film is made coarser than that of the embedded insulating film.

19. The manufacturing method for a semiconductor device of claim 18, wherein the material forming the first insulating film is deposited at a higher temperature under a higher output-power condition in comparison with the material forming the embedded insulating film.

20. The manufacturing method for a semiconductor device of claim 18, further comprising a step (d) in which, after step (c), the first insulating film and the embedded insulating film are etched so that the upper face position of the first insulating film is placed higher than the upper face position of the semiconductor substrate, and is also maintained lower than the upper face position of the embedded insulating film.
